(19) United States
(12) Patent Application Publication
(10) Pub. No.: US 2010/0034015 A1
(43) Pub. Date: Feb. 11, 2010

(54) SEMICONDUCTOR DEVICE

(75) Inventor: Takaharu TSUJI, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/473,832

(22) Filed: May 28, 2009

(30) Foreign Application Priority Data
Aug. 6, 2008 (JP) 2008-203203

(51) Int. Cl. G11C 11/00; G11C 8/08; G11C 11/416; G11C 8/00

(52) U.S. Cl. 365/158; 365/230.06; 365/189.15; 365/189.16; 365/230.03

(57) ABSTRACT

The invention provides a semiconductor device having a lower probability of erroneous inversion of data signal. The MRAM disclosed herein comprises (m+1)×(n+1) memory cells arranged in (m+1) rows and (n+1) columns, digit lines respectively provided in the rows, and bit lines respectively provided in the columns. A magnetizing current Im caused to flow through a digit line in a selected row makes all memory cells half-selected in the row, while a writing current is caused to flow through (n+1) bit lines to write data signals of (n+1) bits into the (n+1) memory cells, the direction of the writing current depending on the logic of each of these data signals. Thus, erroneous inversion of data signal due to a magnetic field in a digit line is avoided.

### CROSS-REFERENCE TO RELATED APPLICATIONS

The disclosure of Japanese Patent Application No. 2008-203203 filed on Aug. 6, 2008 including the specification, drawings and abstract is incorporated herein by reference in its entirety.

### BACKGROUND OF THE INVENTION

The present invention relates to a semiconductor device and, particularly, to a semiconductor device having memory cells to store data signals magnetically.

Nonvolatile semiconductor storage devices are capable of holding stored data even if a power supply voltage is shut off and there is no need to supply the power supply voltage during a standby state. Therefore, such storage devices are widely used in mobile equipment which is required to consume less power.

One of these nonvolatile semiconductor storage devices is an MRAM (Magnetic Random Access Memory) that utilizes a magnetoresistance effect to store data. There is also an MRAM using tunnel magnetoresistive elements having Magnetic Tunnel Junction (MTJ) (for example, refer to Patent Document 1).

A tunnel magnetoresistive element comprises a tunnel insulating layer and two ferromagnetic layers overlying and underlying the tunnel insulating layer, respectively. The tunnel magnetoresistive element has a minimum value of resistance when the magnetic moments of the two ferromagnetic layers are in the same direction, and has a maximum value of resistance when these magnetic moments are in opposite directions. By mapping the maximum resistance and the minimum resistance of the tunnel magnetoresistive element to data signals “0” and “1”, respectively, the data signals “0” and “1” can be stored. The directions of the magnetic moments of the two ferromagnetic layers of the tunnel magnetoresistive element are maintained permanently until a magnetic field of an opposite direction having a power level above a threshold level is applied.

An MRAM comprises a plurality of tunnel magnetoresistive elements arranged in a plurality of rows and a plurality of columns, digit lines provided in each row, and bit lines provided in each column. Writing a data signal into a selected tunnel magnetoresistive element is performed by causing a magnetizing current to flow through a digit line of a selected row and causing a writing current whose direction depends on a write data signal to flow through a bit line of a selected column.

### [Patent Document 1]

Japanese Unexamined Patent Publication No. 2004-185752

### SUMMARY OF THE INVENTION

In hitherto known MRAMs, not only the selected tunnel magnetoresistive element, but also other tunnel magnetoresistive elements in the selected row and column may be disturbed by the resulting magnetic field, and there would be a possibility of occurrence of erroneous inversion of a data signal. The possibility of erroneous inversion of data signal (the probability of erroneous inversion) increases in proportion to the magnitude of the magnetic field that may disturb tunnel magnetoresistive elements. An increase in the probability of erroneous inversion of data signal increases a failure rate of the MRAM used as a memory device, which in turn decreases its reliability.

It is, therefore, a main object of this invention to provide a semiconductor device with reduced probability of erroneous inversion of data signal.

One aspect of the invention relates to a semiconductor device formed over a semiconductor substrate, comprising a memory array, a row decoder, and a writing circuit. The memory array includes M×N memory cells arranged in M rows and N columns (where M, N are each an integer of 2 or greater) to magnetically store data signals respectively, M digit lines respectively provided in the M rows, and N bit lines respectively provided in the N columns. The row decoder selects any one of the M rows according to a row address signal. The writing circuit writes N data signals into N memory cells respectively in a row selected by the row decoder in write operation. This writing circuit includes a digit line driver and N bit line drivers. The digit line driver causes a magnetizing current to flow through a digit line in a row selected by the row decoder to make the N memory cells half-selected in the row. The N bit line drivers are respectively provided in the N columns and receive N data signals, respectively. Each bit line driver causes a writing current whose direction depends on the logic of a data signal it received to flow through the bit line in the corresponding column to write the data signal into the half-selected memory cell in the corresponding column.

Another aspect of the invention resides in a semiconductor device formed over a semiconductor substrate, comprising a memory array. The memory array includes a plurality of memory cells arranged in multiple rows and multiple columns to magnetically store data signals respectively, a plurality of word lines respectively provided in the multiple rows, a plurality of digit lines respectively provided in the multiple rows, and a plurality of bit lines respectively provided in the multiple columns. Each memory cell comprises a magnetoresistive element for storing a data signal when its resistance changes to a certain level and an access transistor coupled in series with the magnetoresistive element between the corresponding bit line and a reference voltage line, wherein the gate of the access transistor is coupled to the corresponding word line. This semiconductor device further comprises a readout circuit and a writing circuit. The readout circuit is coupled to the multiple word lines and the multiple bit lines to read a data signal from at least one memory cell selected out of the plural memory cells. The writing circuit is coupled to the multiple digit lines and the multiple bit lines to write a data signal into at least one memory cell selected out of the plural memory cells. This writing circuit includes a driver transistor which is provided for each row and coupled in series with a digit line in the corresponding row between a voltage supply line and the reference voltage line and becomes conductive when the memory cell in the corresponding row is selected. The driver transistor and each of a plurality of access transistors in the plural memory cells in the corresponding row are disposed adjacently in a bit line extension direction.

A further aspect of the invention relates to a semiconductor device formed over a semiconductor substrate, comprising a plurality of memory cells arranged in multiple rows and multiple columns. Each memory cell includes a magnetoresistive element for storing data magnetically and an access transistor coupled in series with the magnetoresistive element. This semiconductor device further comprises word lines, digit lines, and driver transistors. The word lines are respectively provided in the multiple rows and each word line is coupled to the gate electrodes of all access transistors in the corresponding row. The digit lines are respectively provided in the multiple rows and each digit line applies an induced magnetic field to all magnetoresistive elements in the corresponding row. The driver transistors are provided for each row and each driver transistor becomes conductive when the corresponding digit line is selected in write operation and causes a current to flow through the corresponding digit line to generate the induced magnetic field. Here, a plurality of access transistors respectively included in the plural memory cells are arranged in multiple rows and multiple columns over the semiconductor substrate. A plurality of magnetoresistive elements respectively included in the plural memory cells are arranged in multiple rows and multiple columns in a layer higher than a layer in which the plural access transistors are arranged. Each driver transistor is disposed between two rows of access transistors.

In the semiconductor device according to one aspect of the invention, M×N memory cells are arranged in M rows and N columns and a magnetizing current caused to flow through a digit line in a selected row makes N memory cells half-selected in the row, while a writing current is caused to flow through all N bit lines in the row to write data signals into the N memory cells respectively. Thus, because data signals are written into all memory cells linked to the selected digit line, erroneous inversion of data signal does not occur in the N memory cells linked to the selected digit line. By setting the magnetizing current flowing through a digit line larger than the writing current flowing through bit lines, the probability of occurrence of erroneous judgment in the memory cells linked to the bit line can be reduced.

In the semiconductor device according to another aspect of the invention, a driver transistor for a digit line and each of a plurality of access transistors in the plural memory cells in the corresponding row are disposed adjacently in the bit line extension direction. Accordingly, as compared with hitherto known MRAMs wherein driver transistors are disposed outside the memory array, it is possible to increase the area of a magnetoresistive element and thus reduce the probability of occurrence of erroneous inversion of data signal.

In the semiconductor device according to a further aspect of the invention, a plurality of access transistors respectively included in the plural memory cells are arranged in multiple rows and multiple columns over the semiconductor substrate and a driver transistor is disposed between two rows of access transistors. Accordingly, as compared with hitherto known MRAMs wherein driver transistors are disposed outside the memory array, it is possible to increase the area of a magnetoresistive element and thus reduce the probability of occurrence of erroneous inversion of data signal.

### BRIEF DESCRIPTION OF THE DRAWINGS

FIG. 1 is a block diagram depicting a structure of a semiconductor chip according to Embodiment 1 of the invention.

FIG. 2 is a block diagram depicting a configuration of an MRAM shown in FIG. 1.

FIG. 3 is a block diagram depicting a configuration of a memory block shown in FIG. 2.

FIG. 4 is a circuit diagram depicting a configuration of a memory cell shown in FIG. 3.

FIGS. 5A and 5B are diagrams for the purpose of explaining the operation of a tunnel magnetoresistive element shown in FIG. 4.

FIG. 6 is a diagram for the purpose of explaining write operation of a memory cell shown in FIG. 4.

FIG. 7 is a graph for the purpose of explaining write operation of a memory cell shown in FIG. 4.

FIG. 8 is a diagram for the purpose of explaining read operation of a memory cell shown in FIG. 4.

FIG. 9 is a block diagram depicting drivers for driving a memory block shown in FIG. 2.

FIG. 10 is a circuit diagram depicting a configuration of a WL driver shown in FIG. 9.

FIG. 11 is a circuit diagram depicting a configuration of a DL driver shown in FIG. 9.

FIG. 12 is a circuit diagram depicting a configuration of a BL driver shown in FIG. 9.

FIGS. 13A to 13C are graphs for the purpose of explaining beneficial effects of the semiconductor chip illustrated in FIGS. 1 through 12.

FIG. 14 is another graph for the purpose of explaining beneficial effects of the semiconductor chip illustrated in FIGS. 1 through 12.

FIG. 15 is a block diagram depicting an essential part of the semiconductor chip according Embodiment 2 of the invention.

FIG. 16 is a diagram depicting the layout of a memory block plus DL driver shown in FIG. 15.

FIG. 17 is a cross-sectional view along line XVII-XVII in FIG. 16

FIG. 18 is a diagram depicting a modification example of Embodiment 2.

### DETAILED DESCRIPTION OF THE PREFERRED EMBODIMENTS

### Embodiment 1

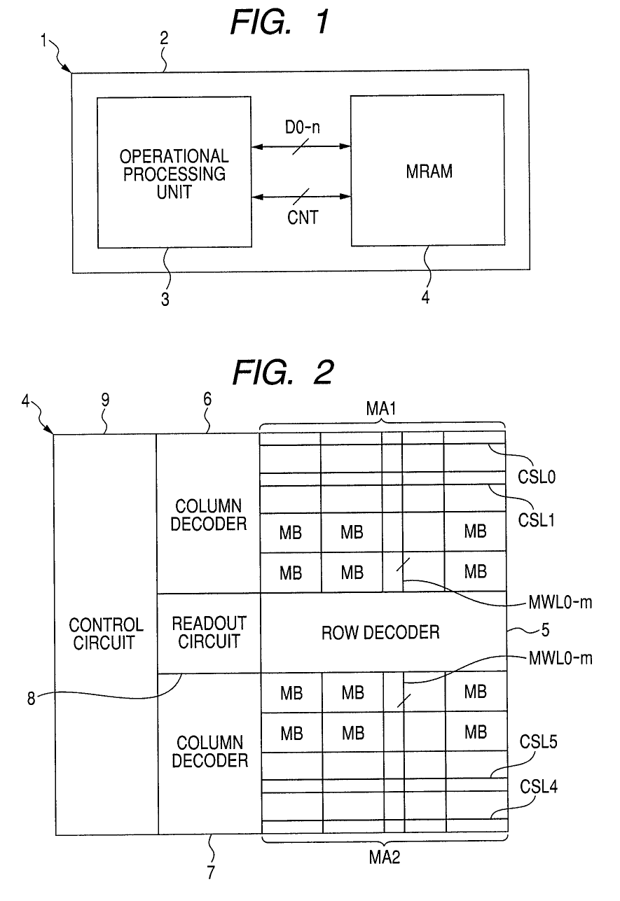

FIG. 1 is a block diagram depicting a structure of a semiconductor chip 1 according to Embodiment 1 of the invention. In FIG. 1, the semiconductor chip 1 comprises a semiconductor substrate 2, an operational processing unit 3 and an MRAM 4 formed over the surface of the substrate. The operational processing unit 3 includes a CPU (Central Processing Unit) which executes predetermined operational processing tasks and a memory controller which controls the MRAM 4, and the like. The MRAM 4 is used to store and read program codes and data.

Control signals CNT including an address signal and the like are provided from the operational processing unit 3 to the MRAM 4 and multi-bit data signals D0 to Dn are transferred between the operational processing unit 3 and the MRAM 4. Here, n is a natural number, e.g., 15, 31, 63, or 127. The higher the number of bits of data signals D0 to Dn which are transferred in parallel between the operational processing unit 3 and the MRAM 4, the higher the operation speed of the semiconductor chip 1 will be. For the semiconductor chip 1, wherein a memory and an operational processing unit are formed over the same chip, it is therefore indispensable to employ data signals D0 to Dn comprised of as a large number of bits as possible.

FIG. 2 is a block diagram depicting a configuration of the MRAM 4. In FIG. 2, the MRAM 4 comprises a memory arrays MA1, MA2, a row decoder 5, column decoders 6, 7, a readout circuit 8, and a control circuit 9. Each of the memory arrays MA1, MA2 includes a plurality of memory blocks MBs arranged in a plurality of rows and a plurality of columns (four rows and four columns in an example as shown).

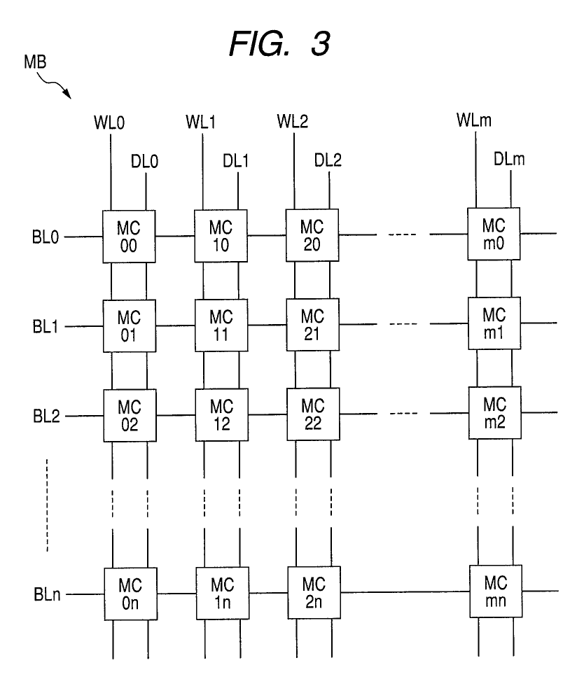

As is depicted in FIG. 3, a memory block MB includes (m+1)×(n+1) memory cells MC00 to MCmn arranged in (m+1) rows and (n+1) columns, (m+1) word lines WL0 to WLm, respectively provided in the (m+1) rows, (m+1) digit lines DL0 to DLm respectively provided in the (m+1) rows, and (n+1) bit lines BL0 to BLn respectively provided in the (n+1) columns. Here, m is a natural number.

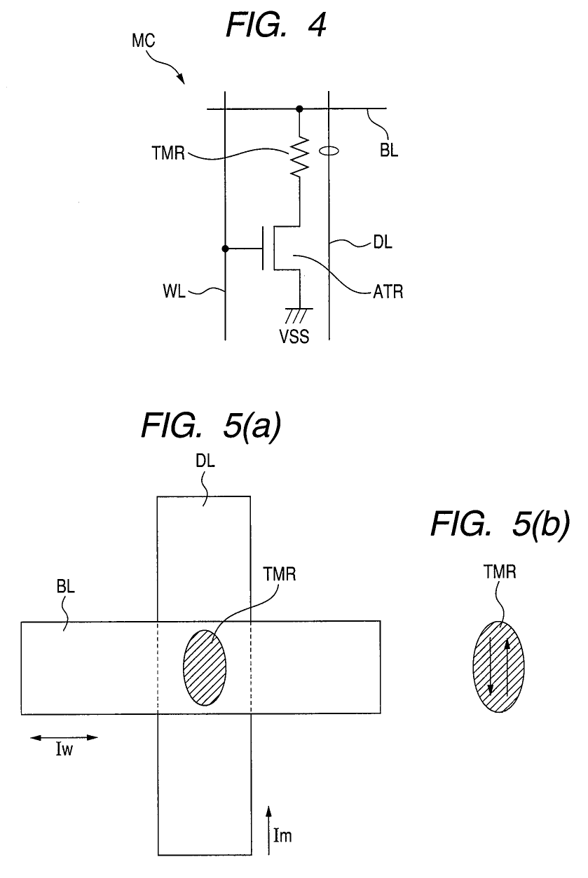

As is depicted in FIG. 4, each memory cell MC includes a tunnel magnetoresistive element TMR and an access transistor (N-channel MOS transistor) ATR. The tunnel magnetoresistive element TMR and the access transistor ATR are coupled in series between the corresponding bit line BL and the ground voltage VSS and the gate of the access transistor ATR is coupled to the corresponding word line WL.

As depicted in FIG. 5A, a tunnel magnetoresistive element TMR is disposed between the corresponding digit line DL and the corresponding bit line BL. An axis of easy magnetization of the tunnel magnetoresistive element TMR is oriented toward a direction in which the digit line DL extends and its axis of hard magnetization is oriented toward a direction in which the bit line BL extends. When causing a magnetizing current Im to flow through the digit line DL and causing a writing current Iw whose direction depends on the logic of a write data signal to flow through the bit line BL, a direction of magnetization of the tunnel magnetoresistive element TMR is oriented toward the positive direction or negative direction with respect to the axis of easy magnetization, depending on the direction of the writing current Iw, which is depicted in FIG. 5B. The tunnel magnetoresistive element TMR is put in a high resistance state or a low resistance state, depending on its direction of magnetization.

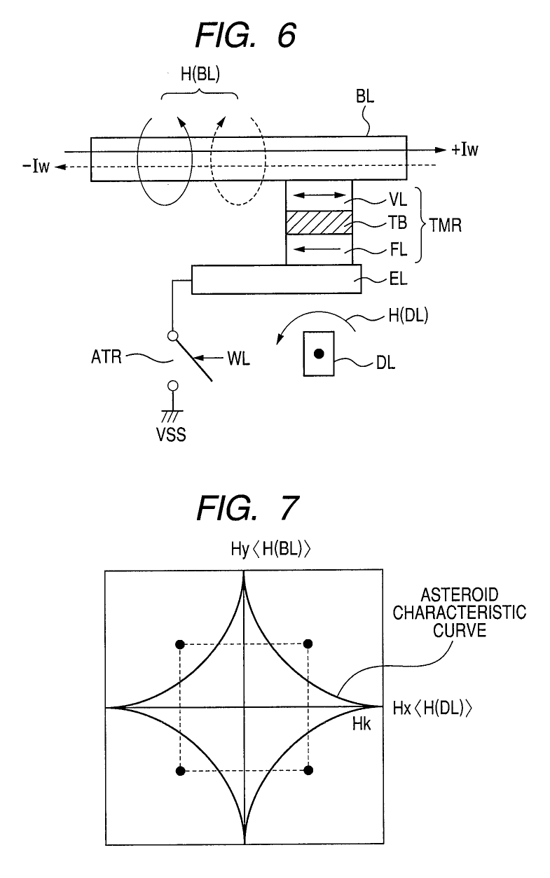

More specifically, as is depicted in FIG. 6, a tunnel magnetoresistive element TMR includes a fixed magnetization layer FL, a tunnel insulating layer TB, and, a free magnetization layer VL stacked between an electrode EL and a bit line BL. The fixed magnetization layer FL and the free magnetization layer VL are made of a ferromagnetic material. The direction of magnetization of the fixed magnetization layer FL is fixed to one direction. Writing into the free magnetization layer VL may take place in either one direction or the order direction of magnetization. When the direction of magnetization of the fixed magnetization layer FL coincides with the direction of magnetization of the free magnetization layer VL, the tunnel magnetoresistive element TMR has a relatively small value of resistance. When the magnetization directions of both are opposite with each other, the tunnel magnetoresistive element TMR has a relatively large value of electrical resistance. Two distinctive levels of resistance of the tunnel magnetoresistive element TMR are mapped to, for example, data signal 0 and 1, respectively.

As is depicted in FIG. 6, when data is written, the word line WL is set to “L” level denoting that the word line is not selected, the access transistor ATR is made non-conductive, and the magnetizing current Im is caused to flow through the digit line DL, while the writing current Iw is caused to flow through the bit line BL. The direction of magnetization of the free magnetization layer VL is determined by combination of the directions of the magnetizing current Im and the writing current Iw.

FIG. 7 is a graph showing a relationship between a magnetic field direction and the directions of the magnetizing current Im and the writing current Iw, when data is written. Referring to FIG. 7, a magnetic field Hx appearing along an abscissa axis denotes a magnetic field H(DL) generated by the magnetizing current Im flowing through the digit line DL. On the other hand, a magnetic field Hy appearing along an ordinate axis denotes a magnetic field H(BL) generated by the writing current Iw flowing through the bit line BL.

A magnetic field direction which is stored into the free magnetization layer VL is newly written, only in a case that the sum of the magnetic fields H(DL) and H(BL) goes outside the region defined by an asteroid characteristic curve shown in the graph. That is, application of the magnetic fields that fall within the region defined by the asteroid characteristic curve does not update the magnetic field direction stored in the free magnetization layer VL. Hence, to update data stored in the tunnel magnetoresistive element TMR by a write operation, it is necessary to cause the currents to flow through both the digit line DL and the bit line BL. Here, the magnetizing current Im of one direction should be caused to flow through the digit line DL, while the writing current Iw whose direction depends on the logic (0 or 1) of a data signal should be caused to flow through the bit line BL. The magnetic field direction, i.e., stored data once stored in the tunnel magnetoresistive element TMR is preserved, remaining nonvolatile, until new data writing is performed.

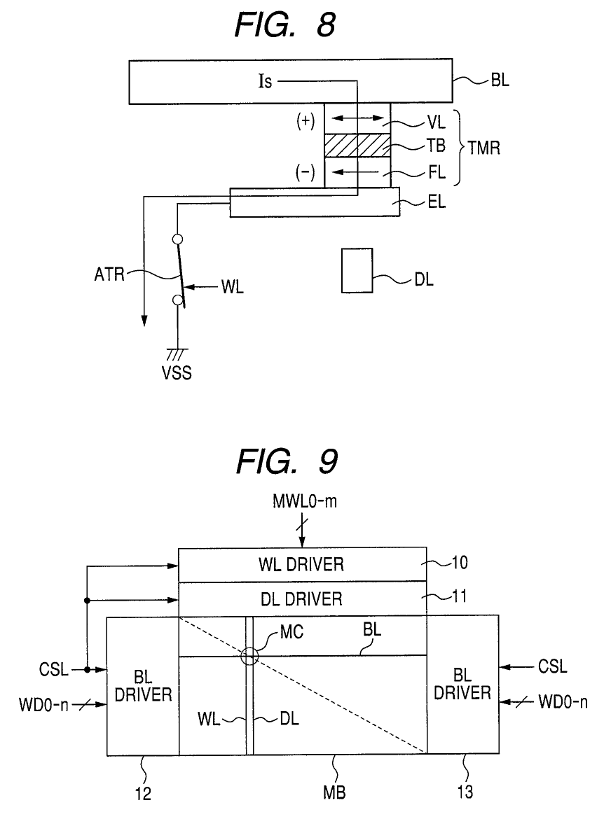

As is depicted in FIG. 8, when data is read, the word line WL is set to “H” level denoting that the word line is selected, the access transistor ATR becomes conductive, a current Is flows from the bit line BL via the tunnel magnetoresistive element TMR and the access transistor ATR to a line to the ground voltage VSS. The value of the current Is changes depending on the value of resistance of the tunnel magnetoresistive element TMR. Hence, by detecting the value of the current Is, it is possible to read the data stored in the tunnel magnetoresistive element TMR.

Returning to FIG. 2, in each of the rows of memory blocks in the memory arrays MA1, MA2, (m+1) main word lines MWL0 to MWLm are arranged which are common for four memory blocks MBs in the respective rows of memory blocks. In four columns of memory blocks in the memory array MA1, column selecting lines CSL0 to CSL3 are arranged respectively, while in four columns of memory blocks in the memory array MA2, column selecting lines CSL4 to CSL7 are arranged respectively. Each column selecting line CSL is common for four memory blocks MBs in the corresponding column of memory blocks.

The row decoder 5 selects any one of a plurality of rows (eight in the example shown) of memory blocks, according to a row address signal provided from the control circuit 9, selects any one main word line MWL out of the (m+1) main word lines MWL0 to MWLm belonging to the selected row of memory blocks, and boosts the selected main word line MWL to “H” level denoting that the main word line is selected.

The column decoders 6, 7 select any one of the columns (eight in the example shown) of memory blocks, according to a column address signal provided from the control circuit 9 and boost the column selecting line CSL provided in the selected column of memory blocks to “H” level denoting that the column is selected.

In read operation, the readout circuit 8 applies a predetermined voltage to each of the (n+1) bit lines BL0 to BLn of the memory block MB selected by the decoders 5 through 7, reads data signals from the (n+1) memory cells MCs selected based on the currents flowing through each bit line BL, and outputs the data signals D0 to Dn of (n+1) bits which have been read out to the operational processing unit 3. The control circuit 9 performs an overall control of the MRAM 4 according to a control signal CNT from the operational processing unit 3.

Further, as is depicted in FIG. 9, in peripheral areas of each of a plurality of memory blocks MBs, a WL driver 10, a DL driver 11, and BL drivers 12, 13 are provided for each memory block MB. Both the WL driver 10 and the DL driver 11 are coupled to the corresponding one of the main word lines MWL0 to MWLm and the corresponding column selecting line CSL. Both the BL drivers 12, 13 are coupled to the corresponding column selecting line CSL and receive write data signals WD0 to WDn. The write data signals WD0 to WDn are data signals D0 to Dn provided from the operational processing unit 3.

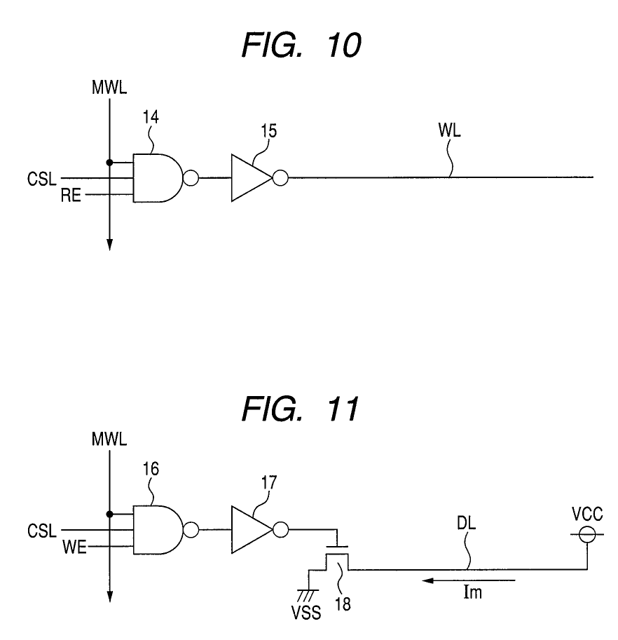

As is depicted in FIG. 10, the WL driver 10 includes a NAND gate 14 and an inverter 15 provided on a respective word line WL. A first input node of the NAND gate 14 is coupled to the corresponding main word line MWL, a second input node thereof is coupled to the corresponding column selecting line CSL, and a third input node thereof receives a read enable signal RE, and an output signal of the NAND gate 14 is supplied to the word line WL via the inverter 15.

In read operation, when the read enable signal RE is set to “H” level representing a read active state, the corresponding main word line MWL is set to “H” level denoting that the main word line is selected by the row decoder 5, and the corresponding column selecting line CSL is set to “H” level denoting that the column is selected by the column decoders 6, 7, then the word line WL is raised to “H” level denoting that the word line is selected. Thereby, the access transistors ATR become conductive in the respective memory cells MCs linked to the word line WL and it becomes possible to read data signals from the (n+1) memory cells MCs linked to the word line WL.

In write operation, the read enable signal RE is set to “L” level representing a read inactive state, the word line WL is fixed to “L” level denoting that the word line is not selected, and the access transistors ATR become non-conductive in the respective memory cells MCs linked to the word line WL.

As is depicted in FIG. 11, the DL driver 11 includes a NAND gate 16, an inverter 17, and an N-channel MOS transistor (driver transistor) 18 provided on a respective digit line DL. A first input node of the NAND gate 16 is coupled to the corresponding main word line MWL, a second input node thereof is coupled to the corresponding column selecting line CSL, and a third input node thereof receives a write enable signal WE, and an output signal of the NAND gate 16 is supplied to the gate of the N-channel MOS transistor 18 via the inverter 17. The drain of the N-channel MOS transistor 18 receives a supply voltage VCC via the digit line DL and the source thereof receives a ground voltage VSS.

In write operation, when the write enable signal WE is set to “H” level representing a write active state, the corresponding main word line MWL is set to “H” level denoting that the main word line is selected by the row decoder 5, and the corresponding column selecting line CSL is set to “H” level denoting that the column is selected by the column decoders 6, 7, then the output signal of the inverter 17 becomes “H” level. Thereby, the N-channel MOS transistor 18 becomes conductive, the magnetizing current Im flow through the digit line DL, the respective memory cells MCs in the row become half-selected, and it becomes possible to write data signals to the (n+1) memory cells MCs in the row. In read operation, the write enable signal WE is set to “L” level representing a write inactive state and the N-channel MOS transistor 18 is switched to a non-conductive state. The magnetizing current Im is set at a sufficiently larger value than the writing current Iw. The reason for this will be described later.

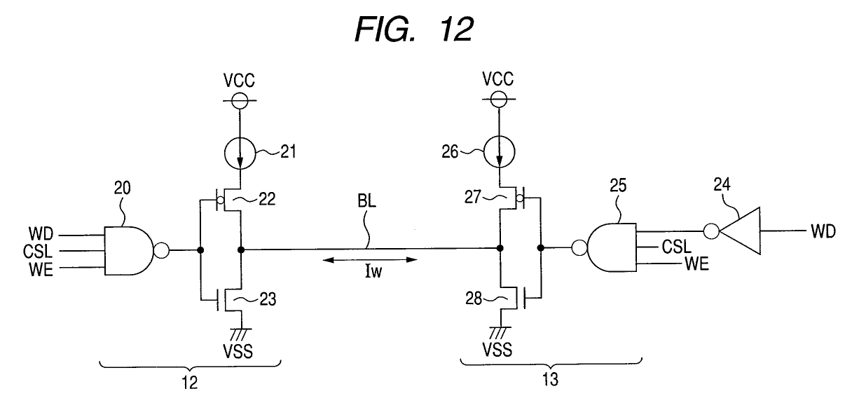

As is depicted in FIG. 12, the BL driver 12 includes a NAND gate 20, a constant current source 21, a P-channel MOS transistor 22, and an N-channel MOS transistor 23 provided on a respective bit line BL. A first input node of the NAND gate 20 receives the corresponding write data signal WD, a second input node thereof is coupled to the corresponding column selecting line CSL, a third input node thereof receives a write enable signal WE, and an output signal of the NAND gate 20 is supplied to the gates of the transistors 22, 23. The constant current source 21 and the transistors 22, 23 are coupled in series between the supply voltage VCC line and the ground voltage VSS line. The drains of the transistors 22, 23 are coupled to one end of the corresponding bit line.

Further, the BL driver 13 includes an inverter 24, a NAND gate 25, a constant current source 26, a P-channel MOS transistor 27, and an N-channel MOS transistor 28 provided on a respective bit line BL. The inverter 24 inverts the write data signal WD. A first input node of the NAND gate 25 receives an output signal of the inverter 24, a second input node thereof is coupled to the corresponding column selecting line CSL, a third input node thereof receives a write enable signal WE, and an output signal of the NAND gate 25 is supplied to the gates of the transistors 27, 28. The constant current source 26 and the transistors 27, 28 are coupled in series between the supply voltage VCC line and the ground voltage VSS line. The drains of the transistors 27, 28 are coupled to the other end of the corresponding bit line BL.

In write operation, when the write enable signal WE is set to “H” level representing a write active state, the corresponding column selecting line CSL is set to “H” level denoting that the column is selected, and the write data signal WD is set to “H” level, then the output signals of the NAND gates 20, 25 become “L” level and “H” level, respectively. Thereby, the transistors 23, 27 become non-conductive, while the transistors 22, 28 become conductive. This causes the writing current Iw to flow from the supply voltage line VCC via the constant current source 21, the P-channel MOS transistor 22, the bit line BL, and the N-channel MOS transistor 28 to the ground voltage VSS line.

When the write enable signal WE is set to “H” level representing a write active state, the corresponding column selecting line CSL is set to “H” level denoting that the column is selected, and the write data signal WD is set to “L” level, then the output signals of the NAND gates 20, 25 become “H” level and “L” level, respectively. Thereby, the transistors 22, 28 become non-conductive, while the transistors 23, 27 become conductive. This causes the writing current Iw to flow from the supply voltage VCC line via the constant current source 26, the P-channel MOS transistor 27, the bit line BL, and the N-channel MOS transistor 23 to the ground voltage VSS line. Thereby, the write data signals WD0 to WDn of (n+1) bits are simultaneously written into the (n+1) memory cells MCs in the selected row of the selected memory block MB.

Next, chip-level operation of the semiconductor chip 1 is briefly described. In write operation, a control signal CNT including an address signal as well as write data signals D0 to Dn are provided from the operational processing unit 3 to the MRAM 4. Based on the address signal from the operational processing unit 3, a row address signal and a column address signal are generated by the control circuit 9 and supplied to the row decoder 5 and the column decoders 6, 7, respectively.

By these decoders 5 through 7, any one memory block MB out of a plurality of memory blocks MBs is selected and then any one of the (m+1) rows of the selected memory block MB is selected. The DL driver 11 causes the magnetizing current Im to flow through the digit line DL in the selected row to make the (n+1) memory cells MCs half-selected in the row. The BL drivers 12, 13 cause the writing current Iw whose direction depends on write data signal to flow through each of the (n+1) bit lines BL0 to BLn in the selected memory block MB. Then, the data signals D0 to Dn are written into the (n+1) memory cells MCs, respectively. In other words, parallel write operation is performed for all memory cells MCs half-selected by one digit line DL in the selected memory block MB.

In read operation, a control signal CNT including an address signal is provided from the operational processing unit 3 to the MRAM 4. Based on the address signal from the operational processing unit 3, a row address signal and a column address signal are generated by the control circuit 9 and supplied to the row decoder 5 and the column decoders 6, 7, respectively.

By these decoders 5 through 7, any one memory block MB out of a plurality of memory blocks MBs is selected and then any one of the (m+1) rows of the selected memory block MB is selected. The word line WL in the selected row is raised to “H” level boosted by the WL driver 10, which in turn makes the access transistors ATR conductive in the memory cells MCs in the row. The readout circuit 8 triggers applying a predetermined voltage to the (n+1) bit lines BL0 to BLn in the selected block MB. Based on the currents flowing through the bit lines BL0 to BLn, data signals D0 to Dn are simultaneously read from the (n+1) memory cells MCs in the selected row, respectively. The data signals D0 to Dn which have been read out are sent to the operational processing unit 3. It should be noted that, since no selection of a digit line DL is performed in read operation, it is sufficiently possible to read bit by bit or read the (n+1) memory cells MCs in a time division manner, if peripheral circuits such as a read control circuit and a sense amplifier are provided as appropriate.

Next, beneficial effects of Embodiment 1 are described. In write operation of a conventional MRAM, a single digit line DL and a single bit line BL are only selected in one memory block MB. Now assume that, for example, one digit line DL1 and one bit line BL0 have been selected in the memory block MB in FIG. 3. In this situation, the magnetizing current Im flows through the digit line DL1 and the writing current Iw flows through the bit line BL0, and data is solely written into a memory cell MC10 at the intersection of the digit line DL1 and the bit line BL0.

At this time, all other memory cells MC00, MC20 to MCm0 affected only by the magnetic field generated by the current Iw in the bit line BL0 and all other memory cells MC11 to MC1n affected only by the magnetic field generated by the current Im in the digit line DL1 become half-selected, but no inversion of data stored in these memory cells occurs. However, the half-selected memory cells MCs, i.e., those disturbed by the magnetic fields have the possibility of occurrence of erroneous inversion of the data signal stored therein. For these memory cells, the possibility of such erroneous inversion (probability of erroneous inversion) increases in proportion to the magnitude of the magnetic field by which the memory cell MC is disturbed. An increase in the probability of erroneous inversion of data signal increases a failure rate of the MRAM used as a memory device, which in turn degrades its reliability.

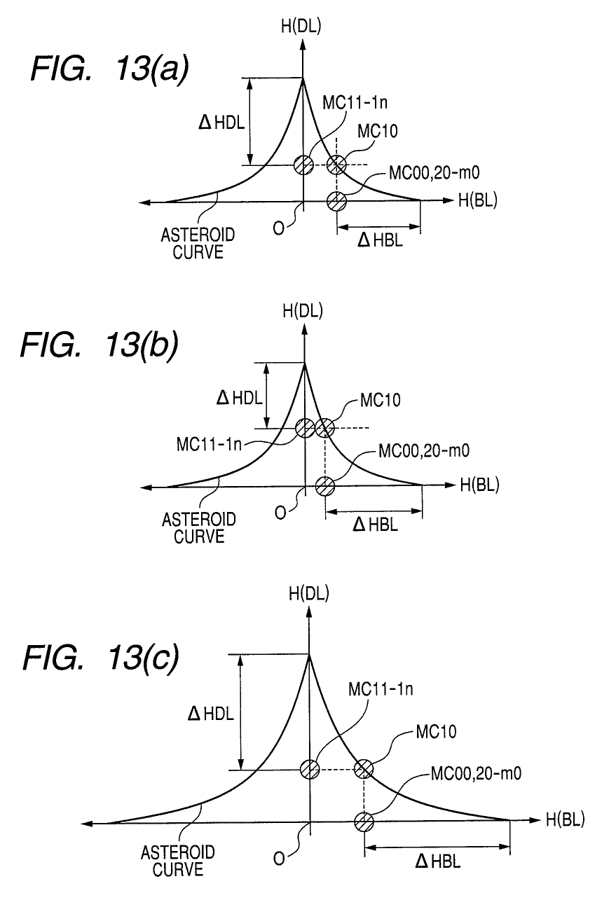

This situation is further explained, using FIGS. 13A to 13C. FIG. 13A is a graph showing magnetic fields applied to memory cells MCs during write operation. In FIG. 13A, the ordinate axis indicates the magnetic field H(DL) generated by the current Im in the digit line DL and the abscissa axis indicates the magnetic field H(BL) generated by the current Iw in the bit line BL. The magnetic field H(DL) generated by the current Im in the digit line DL1 is applied to the memory cells MC10 to MC1n, while the magnetic field H(BL) generated by the current Iw in the bit line BL0 is applied to the memory cells MC00 to MCm0.

Both the magnetic field H(DL) generated in the digit line DL1 and the magnetic field H(BL) generated in the bit line BL0 are applied to the memory cell MC10. The sum of the magnetic fields applied to the memory cell MC10 goes outside the region defined by the asteroid curve and data is written into the memory cell MC10.

The magnetic field H(DL) applied to the memory cells MC11 to MC1n falls within the region defined by the asteroid curve and no data is written into the memory cells MC11 to MC1n. However, the memory cells MC11 to MC1n are disturbed by the magnetic field H(DL). The probability of erroneous inversion occurring in the memory cells MC11 to MC1n is in inverse proportion to a value of a difference ΔHDL between the maximum value of the asteroid curve along the ordinate axis and the magnetic field H(DL) by which the memory cells MC11 to MC1n are affected.

The magnetic field H(BL) applied to the memory cells MC00, MC20 to MCm0 falls within the region defined by the asteroid curve and no data is written into the memory cells MC00, MC20 to MCm0. However, the memory cells MC00, MC20 to MCm0 are disturbed by the magnetic field H(BL). The probability of erroneous inversion occurring in the memory cells MC00, MC20 to MCm0 is in inverse proportion to a value of a difference ΔHBL between the maximum value of the asteroid curve along the abscissa axis and the magnetic field H(BL) by which the memory cells MC00, MC20 to MCm0 are affected.

To increase ΔHBL, one possibility is to move up the magnetic fields applied to the memory cell MC10 along the asteroid curve and to decrease the magnetic field H(BL) and increase the magnetic field H(DL), as is illustrated in FIG. 13B. Due to this, however, ΔHDL will decrease. Conversely, to increase ΔHDL, one possibility is to move down the magnetic fields applied to the memory cell MC10 along the asteroid curve and to decrease the magnetic field H(DL) and increase the magnetic field H (BL). Due to this, however, ΔHBL will decrease. Therefore, conventional MRAMs were configured such that the magnetic fields applied to the memory cell MC10 to be written are set as shown in FIG. 13A, so that both ΔHDL and ΔHBL will be a certain value or above.

In this way, because, if the asteroid curve is fixed, ΔHDL and ΔHBL are determined, only a possible way to increase ΔHDL and ΔHBL is to extend the asteroid curve, as is illustrated in FIG. 13C. However, extending the asteroid curve requires increasing both the magnetizing current Im and the writing current Iw, which in turn increases the consumption current for the semiconductor chip 1. This also requires enhancing the current-driving capabilities of the DL driver 11 and the BL drivers 12, 13, which results in an increase in the layout area for the drivers 11 to 13. To extend the asteroid curve, it is also required to increase the volume (=area×thickness) of the free magnetization layer VL of the tunnel magnetoresistive element TMR. Consequently, the chip area increases.

In contrast, in the present invention, when writing is performed, a single digit line DL and all bit lines BLs are selected. Now assume that, for example, one digit line DL1 and all bit lines BL0 to BLn have been selected in the memory block in FIG. 3. In this situation, the magnetizing current Im flows through the digit line DL1 and the writing current Iw flows through each of the bit lines BL0 to BLn, and data is written into each of the memory cells MC10 to MC1n at the intersections of the digit line DL1 and the bit lines BL0 to BLn.

At this time, all other memory cells MC00 to MC0n, MC20 to MC2n, . . . , MCm0 to MCmn, affected only by the magnetic fields generated by the current Iw in the bit lines BL0 to BLn become half-selected, but no inversion of data stored in these memory cells occurs. The half-selected memory cells MCs, i.e., those disturbed by the magnetic fields have the possibility of occurrence of erroneous inversion of the data signal stored therein. For these memory cells, the possibility of such erroneous inversion (probability of erroneous inversion) increases in proportion to the magnitude of the magnetic field by which the memory cell MC is disturbed.

In the present invention, however, because data signals are written into all memory cells MC10 to MC1n linked to the digit line DL1, no considerations need to be taken for erroneous inversion of data signal due to being disturbed by the current Im in the digit line DL1. Thus, the current Im to flow through a digit line DL is set to a value sufficiently larger than the current Iw to flow through bit lines BLs.

Accordingly, it is possible to sufficiently decrease the disturbance due to the current Iw in the bit lines BL0 to BLn, by which the memory cells MC00 to MC0n, MC20 to MC2n, . . . , MCm0 to MCmn are disturbed, and it is possible to reduce the probability of erroneous inversion of data signal. Consumption current I for write operation of the semiconductor chip 1 is expressed as I=Im+n×Iw (n is, e.g., 64). Hence, reducing the current Iw to flow through bit lines BLs significantly contributes to reducing the consumption current of the semiconductor chip 1.

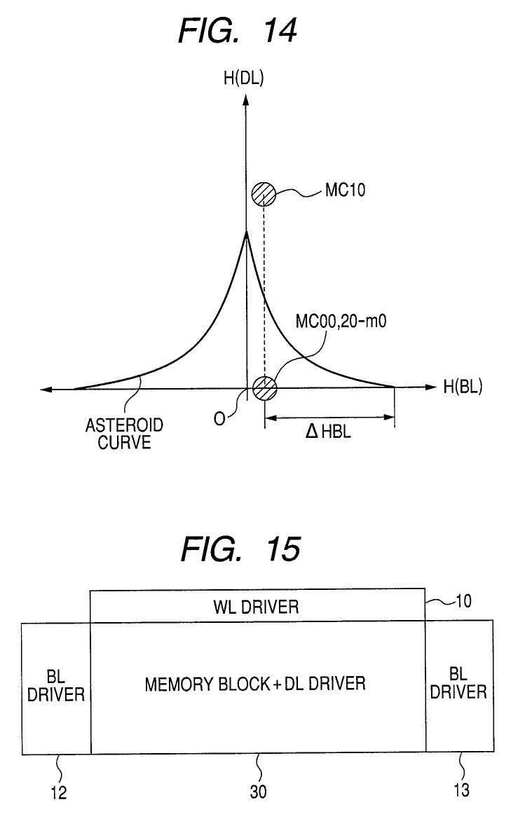

This situation is further explained, using FIG. 14. FIG. 14 is a graph showing magnetic fields applied to memory cells MCs during write operation, which should be compared to FIG. 13A. In FIG. 14, the graph only concerns memory cells MC00 to MCm0 linked to the bit line BL0. A weak magnetic field H(BL) generated by the current Iw in the bit line BL0 is applied to the memory cells MC00 to MCm0, while a strong magnetic field H(DL) generated by the current Im in the digit line DL1 is additionally applied to the memory cell MC10. The sum of the magnetic fields applied to the memory cell MC10 goes outside the region defined by the asteroid curve and data is written into the memory cell MC10.

The magnetic field H(DL) applied to the memory cells MC00, MC20 to MCm0 falls within the region defined by the asteroid curve and no data is written into the memory cells MC00, MC20 to MCm0. The memory cells MC00, MC20 to MCm0 are disturbed by the magnetic field H(BL). The probability of erroneous inversion occurring in the memory cells MC00, MC20 to MCm0 is in inverse proportion to a value of a difference ΔHBL between the maximum value of the asteroid curve along the abscissa axis and the magnetic field H(BL) by which the memory cells MC00, MC20 to MCm0 are affected. In the present invention, however, it is possible to increase ΔHBL and reduce the probability of erroneous inversion in the memory cells MC00, MC20 to MCm0.

As described above, in the present invention, a key point is performing parallel writing to all (n+1) memory cells MCs which are so-called half-selected by a digit line DL selected in write operation, that is, parallel supply of the writing current to (n+1) bit lines to which (n+1) half-selected memory cells MCs are linked. Thus, the number of data signals D0 to Dn or write data signals WD0 to WDn do not necessarily have to be equal to the number of data signal lines for sending the signals (bus width). For instance, 128 signal lines may be provided for 64 bit lines BL with registers employed between a bit line BL and a data signal line. It may also be possible to select two memory blocks MBs at the same time and cause the writing current to flow through 128 (64×2) bit lines BLs simultaneously.

### Embodiment 2

FIG. 15 is a block diagram depicting an essential part of the MRAM of the semiconductor chip according Embodiment 2 of the invention, which should be compared to FIG. 9. In contrast to the semiconductor chip 1 of Embodiment 1, this semiconductor ship shown in FIG. 15 employs a memory block plus DL driver 30 instead of a memory block MB and a DL driver 11. N-channel MOS transistors 18 in DL drivers 11 are distributed within a memory block MB and a NAND gate 16 and an inverter 17 are disposed in proximity to an N-channel MOS transistor 18.

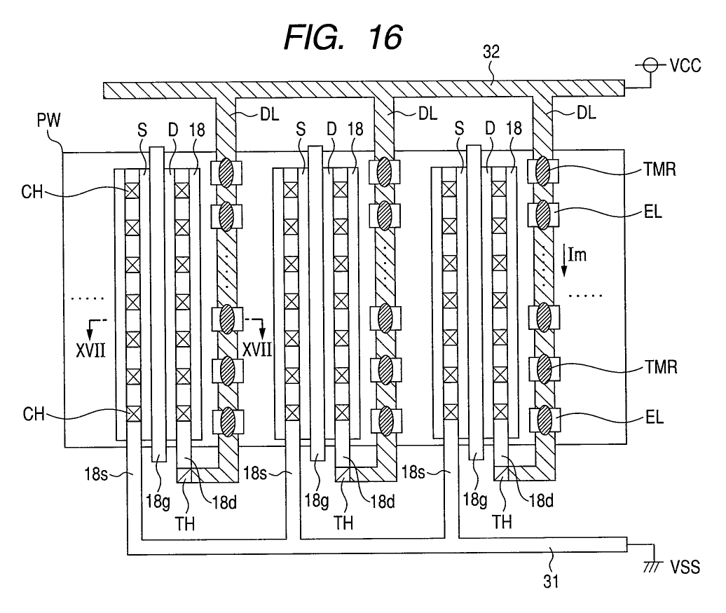

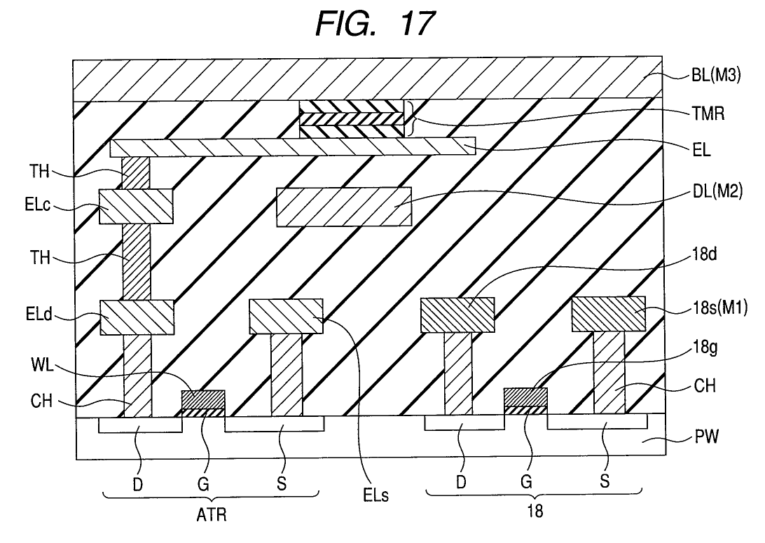

FIG. 16 is a diagram showing a partial configuration of the memory block plus DL driver 30 under bit lines BL. FIG. 17 is a cross-sectional view along line XVII-XVII in FIG. 16. In FIG. 16 and FIG. 17, (m+1) gate electrodes 18g are formed at a predetermined pitch across the surface of P-type well PW of the semiconductor substrate. A gate oxide layer G is formed between each gate electrode 18g and the P-type well PW. A gate electrode 18g corresponds to the gate electrode of an N-channel MOS transistor 18 shown in FIG. 11. In addition, (m+1) word lines WLs are formed at a predetermined pitch across the surface of the P-type well PW. A gate oxide layer G is formed between each word line WL and the P-type well PW. A word line WL also serves as the gate electrode of an access transistor ATR shown in FIG. 4. The(m+1) gate electrodes 18g and the(m+1) word lines WLs are disposed alternately and in parallel. It should be noted that the channel width (vertical length in FIG. 16) of an N-channel MOS transistor 18 is several tens of times (10 to 80 times) as much as the channel width of an access transistor ATR.

On either sides of a gate electrode 18g, the source S and the drain D of an N-channel MOS transistor 18 are formed by dispersion of N-type impurities. Over the source of an N-channel MOS transistor 18, a source wiring 18s is formed via a contact hole CH. Over the drain D of an N-channel MOS transistor 18, a drain wiring 18d is formed via a contact hole CH. The wirings 18s and 18d are formed by a first metal layer M1.

In one side of the P-type well PW (at the bottom of the figure), a ground wiring 31 is formed by the first metal layer M1. The ground wiring 31 is charged with the ground voltage VSS. One end of each source wiring 18s of an N-channel MOS transistor 18 is coupled to the ground wiring 31.

Over each drain wiring 18d, a digit line DL is formed by a second metal wiring layer M2. One end of a digit line DL is coupled to one end of a drain wiring 18d (lower end in the figure) via a through hole TH, In the other side of the P-type well PW (at the top of the figure), a power supply wiring 32 is formed by the second metal layer M2. The power supply wiring 32 is charged with the supply voltage VCC. The other end of each digit line DL is coupled to the power supply wiring 32.

Accordingly, when one N-channel MOS transistor 18 selected becomes conductive, the magnetizing current Im flows from the power supply wiring 32 via the digit line DL and the N-channel MOS transistor 18 to the ground wiring 31.

As is illustrated in FIG. 17, on either side of a word line WL, the source S and the drain D of an access transistor (N-channel MOS transistor) ATR are formed by dispersion of N-type impurities. Over the source S of an access transistor ATR, a source electrode ELs is formed via a contact hole CH. Over the drain D of an access transistor ATR, a drain electrode ELd is formed via a contact hole CH. The electrodes ELs, ELd are formed by the first metal layer M1. The ground voltage VSS is supplied to the source electrode ELs.

Over the drain electrode ELd, a coupling electrode ELc is formed via a through hole. The coupling electrode ELc is formed by the second metal layer M2. Over the coupling electrode ELc, an electrode EL is formed via a through hole TH. The electrode EL is as shown in FIG. 6 and extends horizontally to cover over the digit line DL. On the top surface of the electrode EL in a region above the digit line DL, a tunnel magnetoresistive element TMR is formed. On the top of the tunnel magnetoresistive element TMR, a bit line BL is formed by a third metal layer M3. When the magnetizing current Im flows through the digit line DL and the writing current Iw flows through the bit line BL, the logic of the data signal stored in the tunnel magnetoresistive element TMR is inverted. Other parts of configuration and operation are the same as in Embodiment 1 and, therefore, description thereof is not repeated.

In Embodiment 2, the N-channel MOS transistor 18 for driving a digit line DL and each of a plurality of access transistors ATRs in a plurality of memory cells MCs in the corresponding row are disposed adjacently in a bit line BL extension direction. Thus, as compared with the case where the N-channel MOS transistor 18 is disposed outside the memory block MB, it is possible to increase the area of the tunnel magnetoresistive element TMR and thus decrease the probability of occurrence of erroneous inversion of data signal.

When comparing the case where the N-channel MOS transistor 18 for driving a digit line DL is disposed outside the memory block MB and the case where the N-channel MOS transistor 18 is disposed within the memory block MB as in Embodiment 2, the configuration of Embodiment 2 can be realized by slightly increasing the area of the memory block MB and the total layout area for Embodiment 2 may be smaller. Further, it may be foreseen that, with the advance of a process miniaturization technique for transistors, it may become possible to dispose the N-channel MOS transistor 18 within the memory block MB without increasing the layout area of the memory block MB, if the area of the tunnel magnetoresistive element TMR may be reduced.

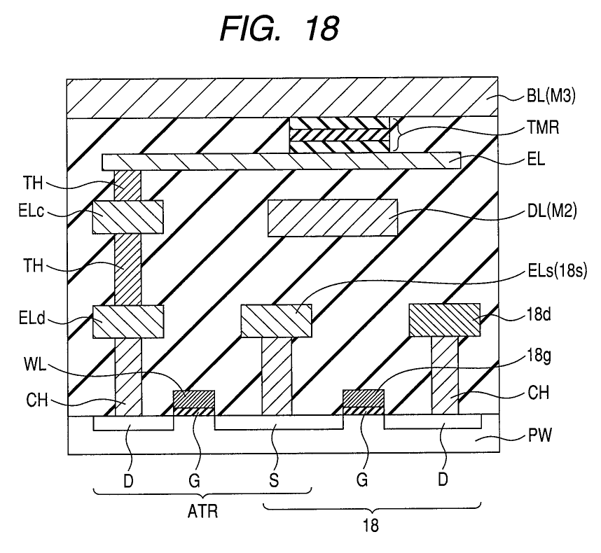

FIG. 18 is a diagram depicting a modification example of Embodiment 2, which should be compared to FIG. 17. In this modification example shown in FIG. 18, the source electrode ELs of the access transistor ATR also serves as the source wiring 18s of the N-channel MOS transistor 18. The gate electrode 18g of the N-channel MOS transistor 18 is disposed between the source electrode ELs and the drain wiring 18d. Beneficial effects of Embodiment 2 are also obtained in this modification example.

The embodiments disclosed herein should be considered as illustrate and non-limiting in all respects. The scope of the present invention is described by the appended claims, not the above descriptions, and the invention is intended to cover all modifications and variants within the meaning and scope equivalent to the scope of the appended claims.

What is claimed is:

1. A semiconductor device formed over a semiconductor substrate, comprising:
a memory array including M×N memory cells arranged in M rows and N columns (where M, N are each an integer of 2 or greater) to magnetically store data signals respectively, M digit lines respectively provided in the M rows, and N bit lines respectively provided in the N columns;
a row decoder for selecting any one of the M rows according to a row address signal; and
a writing circuit for writing N data signals into N memory cells respectively in a row selected by the row decoder in write operation,
the writing circuit including a digit line driver for causing a magnetizing current to flow through a digit line in a row selected by the row decoder to make the N memory cells half-selected in the row; and
N bit line drivers respectively provided in the N columns,
wherein the bit line drivers receive the N data signals, respectively, and each bit line driver causes a writing current whose direction depends on the logic of a data signal each of the bit line driver received to flow through the bit line in the corresponding column to write the data signal into the half-selected memory cell in the corresponding column.

2. The semiconductor device according to claim 1, wherein the magnetizing current is set at a value larger than the writing current.

3. The semiconductor device according to claim 2,
wherein the memory array includes M word lines respectively provided in the M rows,
wherein each memory cell includes:
a magnetoresistive element for storing a data signal when a resistance of the magnetoresistive element changes to a certain level; and
an access transistor coupled in series with the magnetoresistive element between the corresponding bit line and a reference voltage line, wherein the gate of the access transistor is coupled to the corresponding word line, and
wherein the memory array further includes:
a word line driver for boosting a word line to a certain level denoting that the word line is selected in a row selected by the row decoder in read operation and making N access transistors conductive in the N memory cells in the row; and
a readout circuit for reading N data signals from the N memory cells in a row selected by the row decoder via the N bit lines.

4. The semiconductor device according to claim 3,
wherein the digit line driver includes a driver transistor which is provided for each row and coupled in series with a digit line in the corresponding row between a voltage supply line and the reference voltage line and becomes conductive when the corresponding row is selected by the row decoder, and
wherein the driver transistor and each of a plurality of access transistors in a plurality of memory cells in the corresponding row are disposed adjacently in a bit line extension direction.

5. A semiconductor device formed over a semiconductor substrate, comprising:
a memory array divided into a plurality of memory blocks, each memory block including M×N memory cells arranged in M rows and N columns (where M, N are each an integer of 2 or greater) to magnetically store data signals respectively, M digit lines respectively provided in the M rows, and N bit lines respectively provided in the N columns;
a decoder for selecting any one of the memory blocks and any one of the M rows in the selected memory block according to an address signal; and
a writing circuit for writing N data signals into N memory cells respectively in a row selected by the decoder in write operation,
the writing circuit including:
a digit line driver which is provided for each memory block, activated when the corresponding memory block is selected by the decoder, and causes a magnetizing current to flow through a digit line in a row selected by the decoder to make the N memory cells half-selected in the row; and
N bit line drivers which are provided for each memory block and activated when the corresponding memory block is selected by the decoder,
wherein the bit line drivers are respectively provided in the N columns and receive the N data signals, respectively, and each bit line driver causes a writing current whose direction depends on the logic of a data signal each of the bit line driver received to flow through the bit line in the corresponding column to write the data signal into the half-selected memory cell in the corresponding column.

6. A semiconductor device formed over a semiconductor substrate, comprising:
a plurality of memory cells arranged in a plurality of rows and a plurality of columns,
each memory cell including a magnetoresistive element for storing data magnetically and an access transistor coupled in series with the magnetoresistive element;
word lines respectively provided in the rows, wherein each word line is coupled to the gate electrodes of all access transistors in the corresponding row;
digit lines respectively provided in the rows, each digit line applying an induced magnetic field to all magnetoresistive elements in the corresponding row; and
driver transistors provided for each row, each driver transistor becoming conductive when the corresponding digit line is selected in write operation and causing a current to flow through the corresponding digit line to generate the induced magnetic field,
wherein a plurality of access transistors respectively included in the memory cells are arranged in a plurality of rows and a plurality of columns over the semiconductor substrate,
wherein a plurality of magnetoresistive elements respectively included in the memory cells are arranged in a plurality of rows and a plurality of columns in a layer higher than a layer in which the access transistors are arranged, and
wherein the each driver transistor is disposed between two rows of access transistors.

7. The semiconductor device according to claim 6, wherein the gate electrode of the each driver transistor extends in a direction along the word lines.

8. The semiconductor device according to claim 7, wherein each of the driver transistors and each of the access transistors in the corresponding row share a source electrode.

9. The semiconductor device according to claim 8, further comprising bit lines respectively provided in the columns, wherein each bit line applies an induced magnetic field to all magnetoresistive elements in the corresponding column in write operation.

10. The semiconductor device according to claim 9, wherein the channel width of the driver transistors is larger than the channel width of the access transistors.
